(19) United States
(12) Patent Application Publication
(10) Pub. No.: US 2011/0023928 A1
(43) Pub. Date: Feb. 3, 2011

(54) THERMOELECTRIC CONVERSION DEVICE

(75) Inventors: Yao Shih Leng, Taipei (TW); Heng Yung Su, Taipei County (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: MICRO-STAR INTERNATIONAL CORPORATION LIMITED, Taipei County (TW)

(21) Appl. No.: 12/902,951

(22) Filed: Oct. 12, 2010

Related U.S. Application Data
(63) Continuation-in-part of application No. 11/162,535, filed on Sep. 14, 2005.

(51) Int. Cl. H01L 35/02

(52) U.S. Cl. 136/205

(57) ABSTRACT

A thermoelectric conversion device used in a computer uses a thermoelectric conversion module to fully utilize the redundant heat generated by the computer and converts it to electricity based on a temperature difference between a heat generating device and a low temperature device inside the computer. The electricity generated by the thermoelectric conversion module is then delivered to and used to activate a load.

### CROSS-REFERENCE TO RELATED PATENT APPLICATION

This application is a continuation in part of U.S. patent application Ser. No. 11/162,535, filed Sep. 14, 2005, the disclosure of the above identified co-pending application is incorporated herein by reference in its entirety.

### FIELD OF INVENTION

The present invention relates to an energy conversion device, and more specifically, to a thermoelectric conversion device used in a computer.

### BACKGROUND OF THE INVENTION

A prior art computer commonly utilizes a cooling apparatus to reduce high temperature caused by heat generated by internal electronic elements, such as a CPU. There is no effective utilization of the redundant heat generated by these electronic elements. Additionally, research and development of computer power related subjects is mainly focused on enhancing capacity or efficiency of rechargeable batteries of portable computers. Few improvements have been made for reusing the heat generated in the operation of portable computers.

Therefore, a heretofore unaddressed need exists in the art to address the aforementioned deficiencies and inadequacies.

### SUMMARY OF THE INVENTION

In one aspect, the present invention relates to a thermoelectric conversion device. In one embodiment, the thermoelectric conversion device comprises a heat generating device, a low temperature device, a heat-dissipating device, a first cooling fan, a thermoelectric conversion module, a load and a computer casing. The low temperature device is in a meshed structure, and disposed above the heat generating device. The heat-dissipating device is installed between the heat generating device and the low temperature device for dissipating heat from the heat generating device. The heat generating device, the heat-dissipating device, and the low temperature device are stacked in a vertical alignment. The first cooling fan together with the heat-dissipating device sandwiches the low temperature device therebetween. The first cooling fan blows air to the heat-dissipating device through the low temperature device. The thermoelectric conversion module couples with the heat generating device and the low temperature device via two thermal connecting elements for generating power according to a temperature difference between the heat generating device and the low temperature device. The thermoelectric conversion module does not in physical contact with a top surface of the heat generating device. The load is adopted for receiving the power generated by the thermoelectric conversion module. The computer casing accommodates the heat generating device, the low temperature device, the heat-dissipating device, the first cooling fan, the thermoelectric conversion module and the load.

In another aspect, the present invention relates to a thermoelectric conversion device. In one embodiment, the thermoelectric conversion device comprises an electronic element, a low temperature conductor, a heat-dissipating device, a first cooling fan, a thermoelectric conversion module, a second cooling fan and a computer casing. The electronic element has a thermal conductor installed on a surface of the electronic element. The low temperature conductor is in a mesh structure and disposed above the electric element. The heat-dissipating device is installed between the electric element and the low temperature conductor for dissipating heat generated by the electronic element. The thermal conductor, the heat-dissipating device and the low temperature device are stacked in a vertical alignment. The first cooling fan together with the heat-dissipating device sandwiches the low temperature device therebetween. The first cooling fan blows air to the heat-dissipating device through the low temperature device. The thermoelectric conversion module couples with the thermal conductor and the low temperature conductor via two thermal connecting elements for generating power according to a temperature difference between the thermal conductor and the low temperature conductor. The thermoelectric conversion module is adjacent to the electronic element. The second cooling fan couples with the thermoelectric conversion module for receiving power from the thermoelectric conversion module for cooling the electronic element. The computer casing accommodates the electric element, the low temperature conductor, the heat-dissipating device, the first cooling fan, the thermoelectric conversion module and the second cooling fan.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein

FIG. 1A illustrates an exemplary embodiment of an invention related to a computer with thermoelectric conversion.

FIG. 1B illustrates a perspective view of an exemplary embodiment of the invention related to the computer with thermoelectric conversion.

FIG. 1C illustrates an exploded view of the computer of FIG. 1B.

FIG. 1D illustrates an cross sectional view of the computer of FIG. 1B.

FIG. 2 illustrates a block diagram of an embodiment of the invention related to the computer with thermoelectric conversion.

FIG. 3 illustrates a block diagram of an embodiment of the invention related to the computer with thermoelectric conversion.

FIG. 4 illustrates a block diagram of an embodiment of the invention related to the computer with thermoelectric conversion.

### DETAILED DESCRIPTION OF THE INVENTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

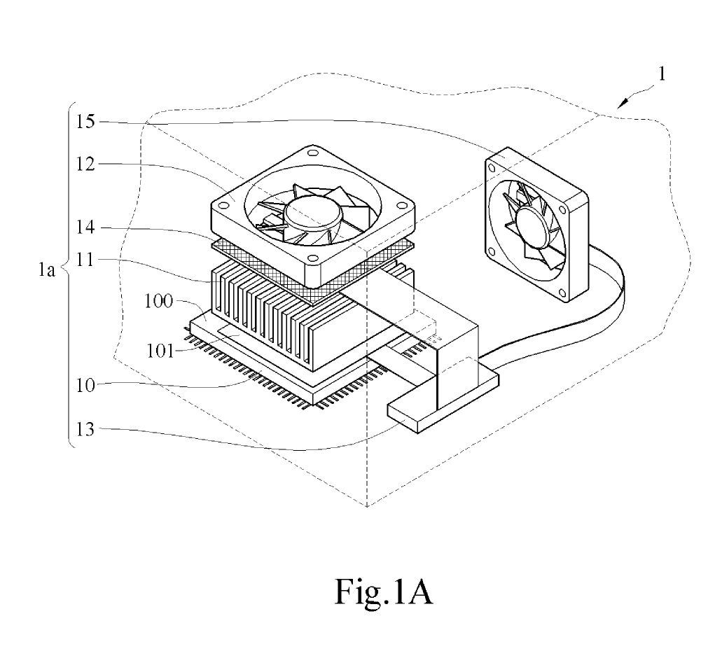

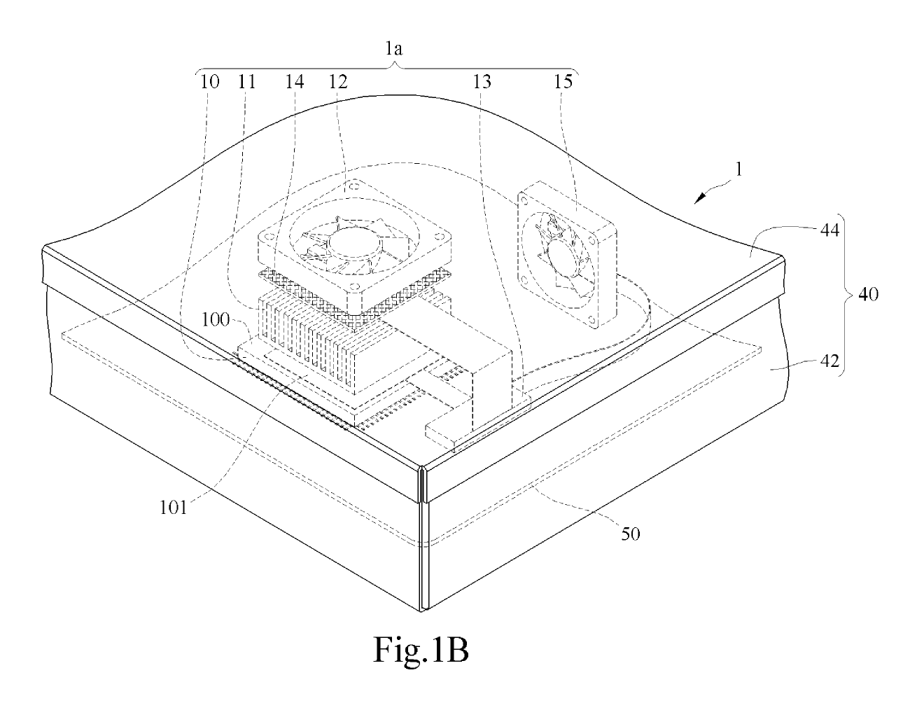

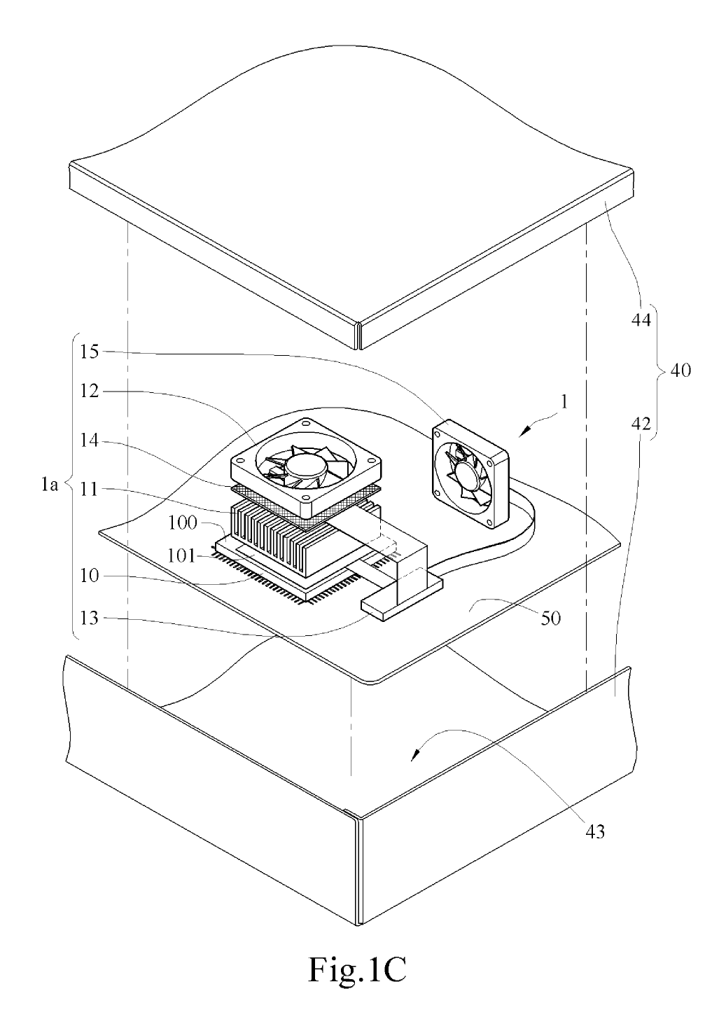

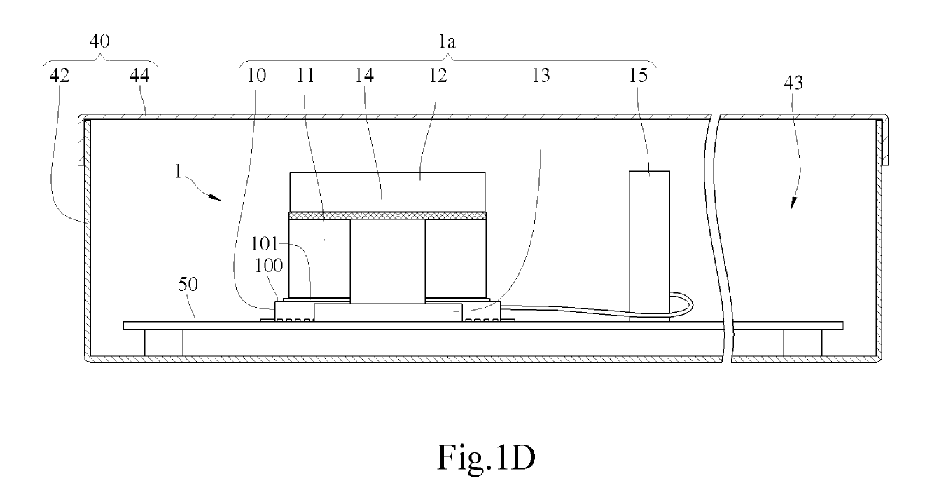

Please refer to FIG. 1A for an exemplary embodiment of a present invention computer 1 with thermoelectric conversion. The computer 1 of the present invention (such as a desktop computer, a microcomputer, a terminal, a portable computer, or a server) comprises a thermal conversion device. The thermal conversion device comprises a conversion unit 1a. The conversion unit 1A comprises a CPU 10 (as a heat generating device, and this can include other elements such as memory or a chip), a heat sink 11, a first cooling fan 12, a thermoelectric conversion module 13, a low temperature device 14 (as a low temperature source, this can be other elements that provide a low temperature source, such as a chassis or a low temperature conductor), and a second cooling fan 15 (as a load). No further description will be made about the heat sink 11 installed above the CPU 10, and the first cooling fan 12 installed above the heat sink 11 since these are well-known prior art elements. FIGS. 1B,1C and 1D illustrate an exemplary embodiment of the present invention where the thermal conversion device installed in a computer comprises the conversion unit 1a and a computer casing 40. The computer casing 40 houses the conversion unit 1a. The computer casing 40, for example, comprises a box 42 with an opening 43 and a cover 44 forming a receiving space together with the box 42 for accommodating the conversion unit 1a. In other words, a printed circuit board 50 which the CPU 10 is electrically connected to and the conversion unit 1a are disposed in the box 42. The cover 44 is disposed on the box 42 and covers the opening 43 so that the printed circuit board 50 and the conversion unit 1a are accommodated in the receiving space formed by the box 42 and the cover 44.

The CPU 10 has a surface 100, and a thermal conductor 101 is installed on the surface 100. The thermal conductor 101 can be made of copper, aluminum, or other material that has a high heat transfer coefficient.

The low temperature device 14 is meshed and made of copper, aluminum, or other material having a high heat transfer coefficient, and is located between the heat sink 11 and the first cooling fan 12. The low temperature device 14 has a lower temperature relative to the thermal conductor 101 since the first cooling fan 12 blows air away from the low temperature device 14.

The thermoelectric conversion module 13 is composed of a P-type semiconductor and an N-type semiconductor, which connects to the thermal conductor 101 with one end and to the low temperature device 14 with the other end. When a temperature difference exists between both ends of the thermoelectric conversion module 13, the carrier density of the high temperature zone is higher than that of the low temperature zone, causing carriers to diffuse from the high temperature zone to the low temperature zone. The uneven distribution of the carriers will make an electromotive force and produce a current via a phenomenon called the Seeback Effect. With the Seeback Effect, the thermoelectric conversion module 13 can convert heat into power according to the thermoelectric conversion principle.

The second cooling fan 15 (the load) is connected to the thermoelectric conversion module 13 with two conducting wires, and can be activated by the power generated by the thermoelectric conversion module 13. The heat generated by the operation of the CPU 10 is conducted from the surface 100 to the thermal conductor 101. The thermoelectric conversion module 13 can then generate power from the heat due to the temperature difference. The power generated by the thermoelectric conversion module 13 can provide the second cooling fan 15 with a current and drive the second cooling fan 15 to cool the CPU 10.

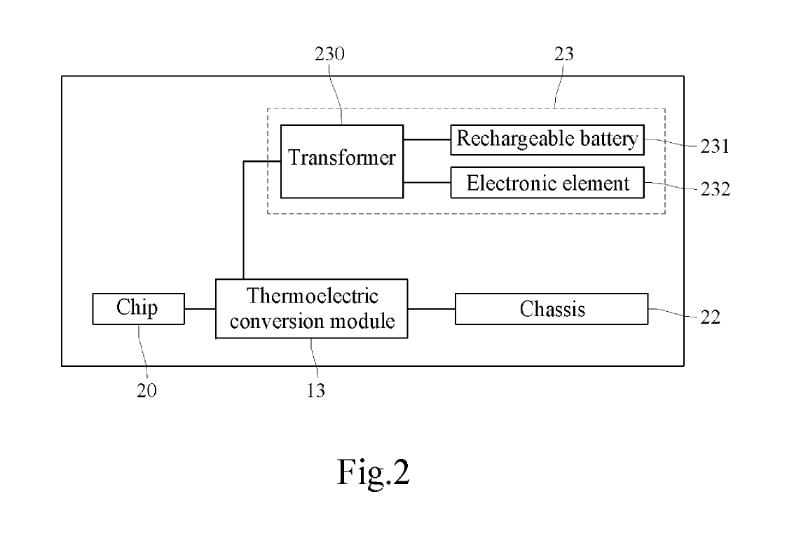

Please refer to FIG. 2 for a second preferred exemplary embodiment of a present invention computer 1 with thermoelectric conversion. Different from the first preferred exemplary embodiment of the present invention, the second preferred exemplary embodiment comprises a chip 20 as the heat generating device, a chassis 22 as the low temperature device, a load 23 having a transformer 230 and a rechargeable battery 231, and an electronic element 232 connected to the transformer 230.

The heat-producing chip 20 transmits heat to the thermoelectric conversion module 13, which then converts the heat to power based on the temperature difference formed by the chip 20 and the chassis 22 and transmits the power to the transformer 230. The transformer 230 transforms the power into electric voltage that charges the rechargeable battery 231 and powers the electronic element 232.

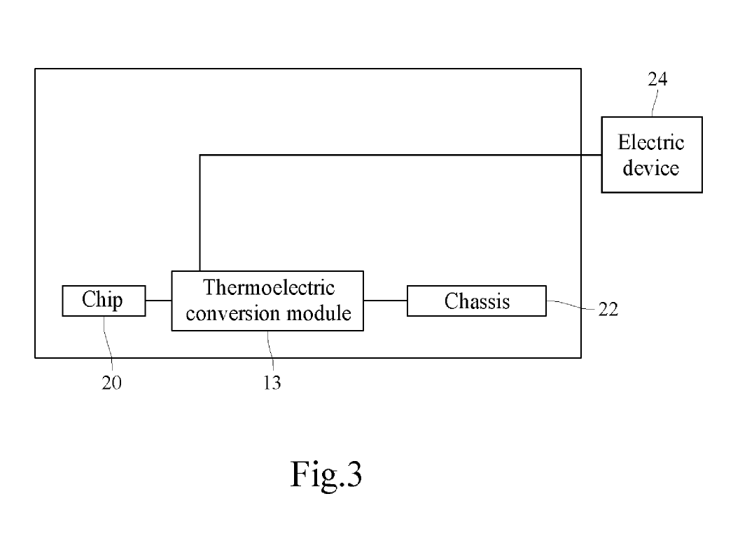

FIG. 3 shows a third preferred exemplary embodiment of a present invention computer 1 with thermoelectric conversion. Different from the second preferred exemplary embodiment, the output of the thermoelectric conversion module 13 connects to an electric device 24 (such as a screen or an indicating light which are not shown in the figure). When a notebook computer, for example, plays music with its screen shutdown, the thermoelectric conversion module 13 supplies power to a small indicating screen or an indicating light for displaying status of playback. In a music-playing mode with the notebook computer's primary functions shutdown, a decoder chip can be taken as the heat generating device.

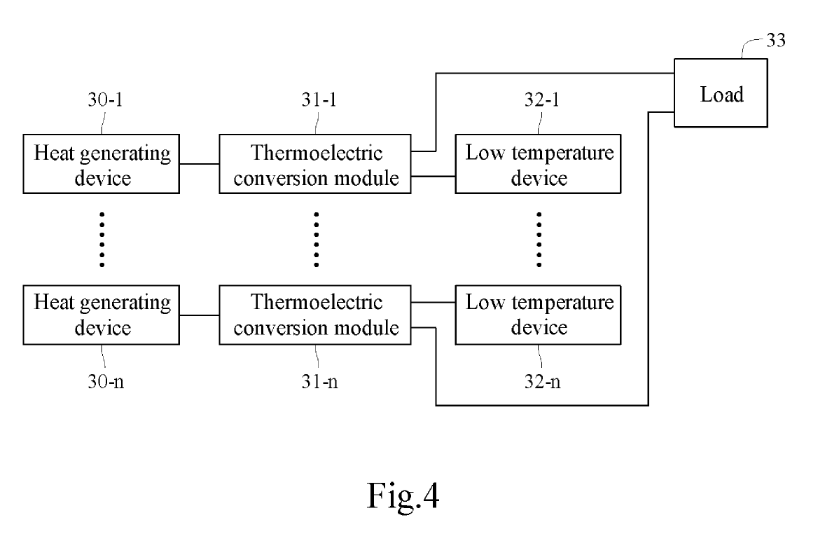

Please refer to FIG. 4 for a fourth preferred exemplary embodiment of the present invention computer 1 with thermoelectric conversion. A plurality of parallel thermoelectric conversion modules 31-1 to 31-n is introduced in the fourth preferred exemplary embodiment. Each thermoelectric conversion module 31-1 to 31-n is respectively coupled between a corresponding heat generating device 30-1 to 30-n (such as a CPU, memory, or any other chip inside a computer, which are not shown in the figure) and one of a plurality of low temperature devices 32-1 to 32-n (such as a low temperature conductor or a chassis). Each thermoelectric conversion module 31-1 to 31-n can convert heat into power based on a temperature difference between the heat generating device and the low temperature device. The load 33 (such a cooling fan, a thermoelectric cooler, a transformer, or an electric device, which are not shown in the figure) is coupled to the plurality of the thermoelectric conversion modules 31-1 to 31-n for receiving the sum of the power from the plurality of the thermoelectric conversion modules 31-1 to 31-n.

The present invention computer with thermoelectric conversion and the thermal conversion device can fully utilize heat generated during the operation of the computer by converting the heat into power that can be used to dissipate heat from the computer itself and lower the computer's working temperature. The power generated by the thermoelectric conversion module of the computer can further provide an auxiliary power source to charge the rechargeable battery of the computer, increasing the available use time. Similarly, the power can even be delivered to other electronic devices making the most of the total energy supplied to the computer.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A thermoelectric conversion device comprising:
a heat generating device;
a low temperature device formed in a meshed structure, and the low temperature device being disposed above the heat generating device;
a heat-dissipating device installed between the heat generating device and the low temperature device for dissipating heat from the heat generating device, and the heat generating device, the heat-dissipating device, and the low temperature device being stacked in a vertical alignment;
a first cooling fan together with the heat-dissipating device to sandwich the low temperature device therebetween and the first cooling fan blowing air to the heat-dissipating device through the low temperature device;
a thermoelectric conversion module coupled with the heat generating device and the low temperature device via two thermal connecting elements for generating power according to a temperature difference between the heat generating device and the low temperature device, the thermoelectric conversion module being not in physical contact with a top surface of the heat generating device;
a load for receiving the power generated by the thermoelectric conversion module; and
a computer casing housing the heat generating device, the low temperature device, the heat-dissipating device, the first cooling fan, the thermoelectric conversion module and the load.

2. The thermoelectric conversion device of claim 1 wherein the heat generating device is an electronic element.

3. The thermoelectric conversion device of claim 2 wherein the electronic element is a CPU, memory, or a chip.

4. The thermoelectric conversion device of claim 2 wherein the electronic element includes a thermal conductor connected with the thermoelectric conversion module.

5. The thermoelectric conversion device of claim 1 wherein the low temperature device is a chassis, or a low temperature conductor.

6. The thermoelectric conversion device of claim 1 wherein the load is a second cooling fan.

7. The thermoelectric conversion device of claim 1 wherein the load is a thermoelectric cooler.

8. The thermoelectric conversion device of claim 1 wherein the load comprises:
a transformer for transforming power received from the thermoelectric conversion module; and
a rechargeable battery for receiving power from the transformer.

9. The thermoelectric conversion device of claim 8 further comprising an electronic element for receiving power from the transformer.

10. The thermoelectric conversion device of claim 1 wherein the load comprises:
a transformer for transforming power received from the thermoelectric conversion module; and
an electronic element for receiving power from the transformer.

11. The thermoelectric conversion device of claim 1 wherein the load is an electric device.

12. The thermoelectric conversion device of claim 11 wherein the electric device is an indicating screen, or an indicating light.

13. The thermoelectric conversion device of claim 1 wherein the thermoelectric conversion device is a desktop computer, a microcomputer, a terminal, a portable computer, or a server.

14. The thermoelectric conversion device of claim 1 wherein the heat-dissipating device is a heat sink.

15. A thermoelectric conversion device comprising:
an electronic element having a thermal conductor installed on a surface of the electronic element;
a low temperature conductor formed in a mesh structure, and the low temperature device being disposed above the electric element;
a heat-dissipating device installed between the electric element and the low temperature conductor for dissipating heat generated by the electronic element, and the thermal conductor, the heat-dissipating device and the low temperature device being stacked in a vertical alignment;
a first cooling fan together with the heat-dissipating device to sandwich the low temperature device therebetween and the first cooling fan blowing air to the heat-dissipating device through the low temperature device;
a thermoelectric conversion module coupled with the thermal conductor and the low temperature conductor via two thermal connecting elements for generating power according to a temperature difference between the thermal conductor and the low temperature conductor, the thermoelectric conversion module being adjacent to the electronic element;
a second cooling fan coupled to the thermoelectric conversion module for receiving power from the thermoelectric conversion module for cooling the electronic element; and
a computer casing accommodating the electric element, the low temperature conductor, the heat-dissipating device, the first cooling fan, the thermoelectric conversion module and the second cooling fan.

16. The thermoelectric conversion device of claim 15 wherein the electronic element is a CPU.

17. The thermoelectric conversion device of claim 15 wherein the thermoelectric conversion device is a desktop computer, a microcomputer, a terminal, a portable computer, or a server.

18. The thermoelectric conversion device of claim 15 wherein the heat-dissipating device is a heat sink.
